(19) United States
(12) Patent Application Publication
(10) Pub. No.: US 2014/0086712 A1
(43) Pub. Date: Mar. 27, 2014

(54) TRANSPORTNG APPARATUS AND PROCESSING APPARATUS

(71) Applicant: Tokyo Electron Limited, Tokyo (JP)

(72) Inventors: Katsuhiko Oyama, Iwate (JP); Yasushi Takeuchi, Iwate (JP)

(73) Assignee: Tokyo Electron Limited, Tokyo (JP)

(21) Appl. No.: 14/028,640

(22) Filed: Sep. 17, 2013

(30) Foreign Application Priority Data
Sep. 24, 2012 (JP) 2012-209825

(51) Int. Cl. H01L 21/677

(52) U.S. Cl. CPC H01L 21/677
USPC 414/222.01

(57) ABSTRACT

Provided is a transporting apparatus which suppresses wafers accommodated therein from being contaminated by particles existing inside the transporting apparatus even when wafers charged with electricity are accommodated in the accommodating apparatus. The transporting apparatus includes: a holding table including a first positioning pin that positions an article to be transported and configured to transfer an object to be processed which is accommodated in the article; an arm unit configured to grasp the article so as to dispose the article on the holding table; and a support unit configured to fix the article disposed on the holding table. In particular, at least one of the first positioning pin, the arm unit, and the support unit includes a ground element.

### CROSS-REFERENCE TO RELATED APPLICATIONS

This application is based on and claims priority from Japanese Patent Application No. 2012-209825, filed on Sep. 24, 2012, with the Japan Patent Office, the disclosure of which is incorporated herein in its entirety by reference.

### TECHNICAL FIELD

The present disclosure relates to a transporting apparatus and a processing apparatus.

### BACKGROUND

In manufacturing semiconductor devices, processings such as, for example, a film forming processing, an oxidation processing and an annealing processing, are carried out for a semiconductor wafer (“wafer”) which is a workpiece to be processed. In such a case, a cassette configured to accommodate a plurality of wafers is transported to a predetermined position between, for example, a mounting table on which the cassette is mounted, a stocker configured to temporarily stock the cassette, and a holding table configured to hold the cassette when the wafers accommodated in the cassette are transported to a wafer boat. There are two types of cassettes configured to accommodate a plurality of wafers including an open type cassette and a FOUP (Front Opening Unified Pod) of a closed type cassette.

A FOUP is configured to accommodate a plurality of, for example, about 25 wafers within a housing in a state where an opening of the housing is closed by a detachable cover. When transporting wafers using the FOUP, foreign matters such as particles from the outside of the FOUT are not attached to the wafers since the FOUP is closed. See, for example, Japanese Patent Laid-Open Publication No. 2008-141130.

In a wafer processing for manufacturing semiconductor devices, the FOUP in which wafers are accommodated is transported from a mounting table or a stocker of a processing apparatus to a holding region first. Then, the wafers within the FOUP are carried out, subjected to various processings and then accommodated in the FOUP again so as to be transported to the next processing.

### SUMMARY

A transporting apparatus according to the present disclosure includes: a holding table having a first positioning pin that positions an article to be transported and configured to transfer an object to be processed which is accommodated in the article; an arm unit configured to grasp the article so as to dispose the article on the holding table; and a support unit configured to fix the article disposed on the holding table. At least one of the first positioning pin, the arm unit and the support unit includes a grounding element.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating a processing apparatus using a transporting apparatus according to an exemplary embodiment of the present disclosure.

FIG. 2 is a schematic view illustrating an example of the transporting apparatus according to the present exemplary embodiment.

FIG. 3 is a schematic view illustrating another example of the transporting apparatus according to the present exemplary embodiment.

FIG. 4 is a schematic view illustrating an accommodation apparatus transported by the transporting apparatus according to the present exemplary embodiment.

FIG. 5 is a schematic view illustrating a bottom surface of the accommodation apparatus of FIG. 4.

FIGS. 6A to 6D are schematic views for describing an electrifying property of the accommodation container of the present exemplary embodiment.

FIGS. 7A and 7B are schematic views for describing an electrifying property of the accommodation container disposed on the transporting apparatus of the present exemplary embodiment.

FIGS. 8A to 8D are graphs representing examples of measurement results of surface potential of the accommodation container according to the present exemplary embodiments.

FIG. 9 is a schematic view illustrating the increase of the number of particles of the accommodation container according to the present exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

When wafers are recovered after completing various processes, the wafer themselves may be charged with electricity (“electrified”). Specifically, wafers are processed under a dried atmosphere or a nitrogen atmosphere in many cases and in such an atmosphere, the wafers are hardly discharged. Thus, wafers accommodated in a FOUP after completing various processes tend to be electrified, i.e., charged with electricity. The accommodated wafers charged with electricity may attract foreign matter such as particles attached to, for example, an inner wall surface of the FOUP, so that the wafers may be contaminated.

Accordingly, the present disclosure provides a transporting apparatus in which wafers may be prevented from being contaminated by particles existing therein even when an electrified wafer is accommodated therein.

A transporting apparatus according to an aspect of the present disclosure includes: a holding table having a first positioning pin that positions an article to be transported and configured to transfer an object to be processed which is accommodated in the article; an arm unit configured to grasp the article so as to dispose the article on the holding table; and a support unit configured to fix the article disposed on the holding table. At least one of the first positioning pin, the arm unit, and the support unit includes a ground element.

In the transporting apparatus described above, the first positioning pin may include the grounding element, and the article to be transported may include a positioning groove which is engaged with the first positioning pin.

The transporting apparatus described above may further include: a mounting table having a second positioning pin that positions the article to be transported and configured to carry in/out the article to be transported; and an accommodation shelf having a third positioning pin that positions the article to be transported and configured to accommodate the article to be transported. Here, at least one of the second positioning pin and the third positioning pin may include the grounding element.

In the transporting apparatus described above, each of the first, second and third positioning pins may be configured by three pins, and at least one of the three pins may include the grounding element.

In the transporting apparatus described above, the arm unit may have the grounding element, and the article to be transported may include a flange to be grasped by the arm unit.

In the transporting apparatus described above, the support unit may include the grounding element, the holding table may be configured to be movable, and the support unit may be engaged with at least a portion of the top surface of the article to be transported so as to fix the article to be transported which is disposed on the holding table.

In the transporting apparatus described above, the article to be transported may be a closed cassette in which at least a semiconductor wafer is accommodated.

The processing apparatus of the present disclosure includes the transporting apparatus described above; and a heat treatment apparatus configured to perform a heat treatment for the object to be processed which is transferred by the holding table.

With the features described above, a transporting apparatus may be provided in which wafers are prevented from being contaminated by particle existing therein, even when an electrified wafer is accommodated therein.

Hereinafter, an exemplary embodiment of the present disclosure will be described with reference to the accompanying drawings.

[Transporting Apparatus and Processing Apparatus]

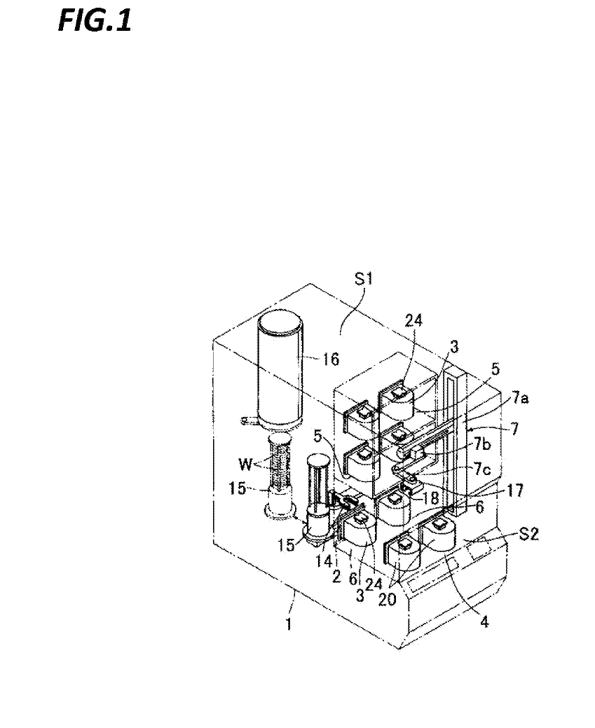

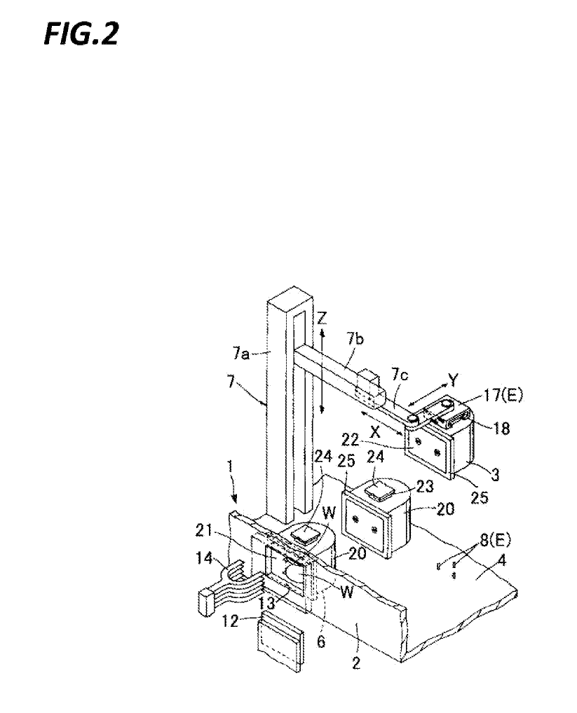

An exemplary configuration of a transporting apparatus according to the present disclosure and a processing apparatus provided with the transporting apparatus will be described. FIG. 1 is a schematic view illustrating a processing apparatus using a transporting apparatus according to the exemplary embodiment of the present disclosure. FIG. 2 is a schematic view illustrating the exemplary transporting apparatus according to the present embodiment.

A processing apparatus 1 according to the present exemplary embodiment conducts various processes such as, for example, a film forming processing, an oxidation processing, a diffusion processing and an annealing processing, for an object to be processed (e.g., a semiconductor wafer W).

The processing apparatus 1 is configured to be accommodated in a case and divided into a wafer transporting region S1 and an accommodation container transporting region S2 by a wall 2. The wafer transporting region S1 is typically under an inert gas atmosphere (e.g., a nitrogen gas atmosphere) so as to prevent a wafer W carried into the wafer transporting region S1 from being oxidized. Meanwhile, the accommodation container transporting region S2 is typically under an air atmosphere. In particular, the wafer transporting region S1 is maintained to be high in cleanliness and a low oxygen density as compared to the accommodation container transporting region S2.

The accommodation container transporting region S2 may be provided with a filter unit such as, for example, a HEPA filter or an ULPA filter, at the ceiling portion thereof such that the accommodation container transporting region S2 may be supplied with purified air by the filters.

A mounting table 4 is disposed in the accommodation container transporting region S2. The mounting table 4 is configured to dispose closed accommodation containers (FOUPs) 20 which are articles to be transported. In addition, the processing apparatus 1 is provided with an accommodation shelf 5 configured to primarily accommodate the accommodation containers 20, and a holding table 6 configured to transfer wafers W from the accommodation containers 20 to the wafer transporting region S1. The transportation of the accommodation containers 20 among the mounting table 4, the accommodation shelf 5, and the holding table 6 may be carried out through a cassette transporting mechanism 7 (to be referred to as a “transporting apparatus 7”). In addition, the mounting table 4 and the holding table 6 generally have the same configuration.

As illustrated in FIG. 2, positioning pins 8 that position an accommodation container 20 (also referred to as “kinematic pins”) are provided on a holding surface (mounting surface) of the holding table 6. In FIG. 2, three positioning pins 8 are assigned for one accommodation container 20 held on the holding table 6 but the present disclosure is not limited thereto. For example, four positioning pins 8 may be assigned for one accommodation container 20. Further, the positioning pins 8 may also be provided on the mounting surface of the mounting table 4 and the accommodation surface (mounting surface) of the accommodation shelf 5.

The accommodation shelf 5 is disposed typically, but not exclusively, above the holding table 6. In addition, the accommodation shelf 5 is typically configured by two or more tiers of shelves, and each of the shelves is configured to accommodate two accommodation containers 20.

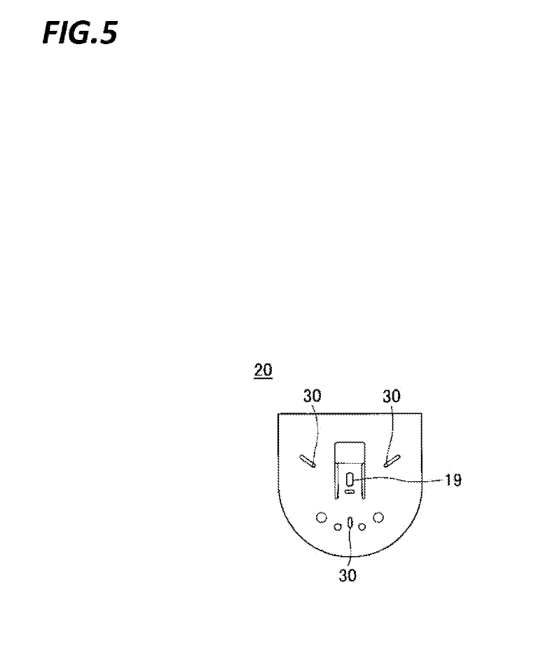

As illustrated in FIG. 1, for example, two holding tables 6 are arranged to be parallel to the wall 2. In addition, the holding surface of each holding table 6 is configured to allow an accommodation containers 20 held on the holding table 6 to be moved in the front and rear direction (in the Y-direction in FIG. 2). Further, the holding table 6 may be formed with a hook unit (not illustrated) and the hook unit may be configured such that, when the hook unit is engaged with a recess 19 (see, e.g., FIG. 5) formed on the bottom surface of an accommodation container 20, the accommodation container 20 may be fixed to the holding table 6.

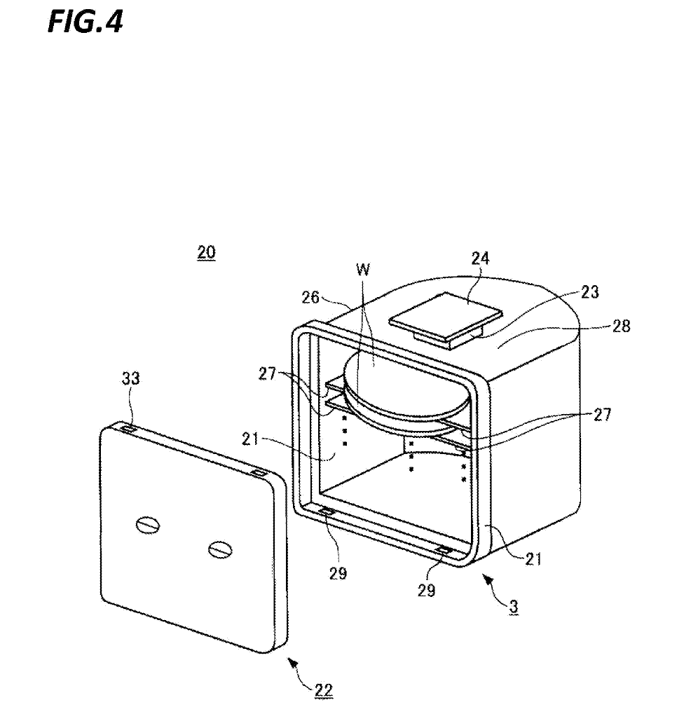

The accommodation container 20 has a flange portion 25 having an opening 21 which is hermetically covered by a cover 22 (see, e.g., FIG. 4). An example of a detailed configuration of the accommodation container 20 will be described later. Further, on the bottom surface, the accommodation container 20 includes positioning grooves 30 which are engaged with the positioning pins 8 and a recess 19 which is engaged with the hook unit as described above.

The transporting apparatus 7 is configured to include a Z-axis lifting unit 7a, an X-axis horizontal unit 7b, and an articulated arm 7c. At the front end of the articulated arm 7c, an arm unit 17 of which the cross-section has an approximately U shape is installed, and holding pieces 18 which are inwardly directed are formed on the both sides of the bottom end of the arm unit 17. The holding piece 18 is configured to be engaged with the flange 24 of the accommodation container 20. In another exemplary embodiment, each of the holding pieces 18 may be configured to protrude as a claw shape. Further, optical sensors (not illustrated) may be installed at the opposite ends and the central area of a side surface of the arm unit 17. When the existence/non-existence and the holding state of the flange 24 are confirmed by the optical sensors, the accommodation container 20 may be stably transported.

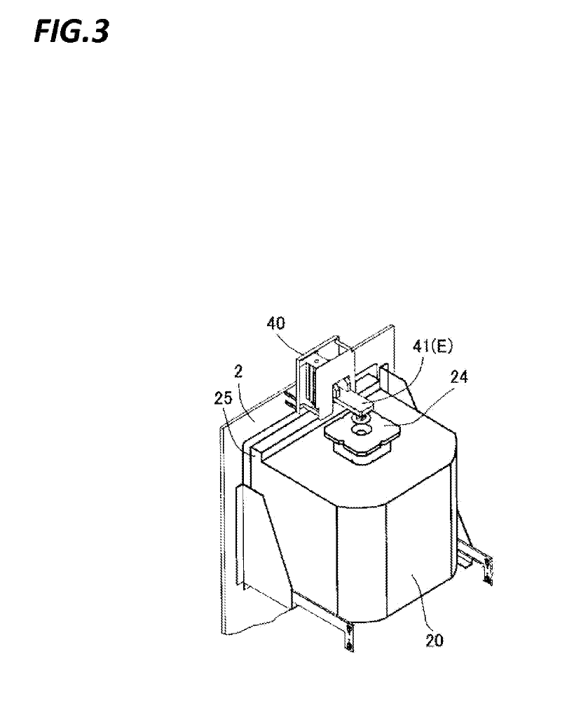

The carry-in of wafers W within the accommodation container 20 from the accommodation container transporting region S2 to the wafer transporting region S1 and the carry-out of wafers from the wafer transporting region S1 to the accommodation container transporting region S2 are carried out, for example, as follows. FIG. 3 is a schematic view illustrating another example of the transporting apparatus according to the present exemplary embodiment.

An accommodation container 20 is disposed on the mounting surface of a holding table 6 by the arm unit 17 as described above in such a manner that the positioning grooves 30 are engaged with the positioning pins 8 and the hook unit is engaged with the recess 19. In general, when the accommodation container 20 is disposed on the holding table 6, the holding table 6 is moved to the wall 2 side so that the flange portion 25 comes into contact with the wall 2. In this state, a fixing device 40 having, for example, a fixing unit 41 as illustrated in FIG. 3 is moved up and down and engaged with the flange 24 so that the contact state of the accommodation container 20 in relation to the wall 2 is maintained. The holding table 6 may be stationary so that the holding table 6 may not be moved to the wall 2 side. In such a case, the holding table 6 is installed at a position where the flange portion 25 of the accommodation container 20 comes into contact with the wall 2 when the accommodation container 20 is disposed on the holding table 6. In this state, the fixing device 40 having, for example, the fixing unit 41 as illustrated in FIG. 3 is moved up and down and engaged with the flange 24 so that the contact state of the accommodation container 20 in relation to the wall 2 may be maintained.

In FIG. 3, a camping device having a clamp as the fixing unit is illustrated and it is exemplified that the clamping device is engaged with and fixed to the flange 24 at the top of the accommodation container 20. However, the present disclosure is not limited thereto. For example, the fixing device 40 may be configured to engage with lateral surfaces of the accommodation container 20 and fix the accommodation container 20.

Subsequently, as illustrated in FIG. 2, the cover 22 is released with an unlocking device (not illustrated) in a state where the flange portion 25 is in contact with the wall 2 of the processing apparatus 1 and a gate 12 installed on the wall 2 is differentially operated so that an opening window 13 formed through the wall 13 is opened. As illustrated in FIG. 1, in the wafer transporting region S1, a vertical heat treatment furnace 16 is installed in which the lower end of the heat treatment furnace 16 is opened as a furnace opening hole. Below the heat treatment furnace 16, a wafer boat 15 is disposed, in which the wafer 15 maintains a plurality of wafers W as a shelf type. The wafers W are transferred from the opening window 13 and loaded on the wafer a wafer transfer device 14. Subsequently, the wafer boat 15 is loaded in the heat treatment furnace 16 by an elevator device (not illustrated) and then a predetermined processing process is performed. The convey-out of the wafers W after finishing the processing is carried out as follows: the wafer boat 16 is unloaded from the heat treatment furnace 16, and to the contrary to the above-described carry-in, the wafers W are transferred from the opening window 13 positioned at the holding table 6 to the accommodation container 20. Then, the cover 22 is attached to the accommodation container 20 with a locking device (not illustrated), and the accommodation container 20 is transported from the accommodation container transporting region S2 to the next process by the transporting apparatus 7.

In the present exemplary embodiment, at least one of a positioning pin 8, the arm unit 17 and the fixing unit 41 is provided with a grounding element E. In the case in which the grounding element E is provided on the positioning pin 8, when a plurality of positioning pins 8 (in the example of FIG. 2, three positioning pins), one of the positioning pins 8 may be provided with the grounding element E or two or more positioning pins may be provide with the grounding element E. The effects obtained by installing the grounding element E on at least one of the positioning pin 8, the arm unit 17 and the fixing unit 41 will be described in detail below.

[Closed Accommodation Container]

The configuration of a closed accommodation container 20 will be described in detail with reference to drawings. FIG. 4 is a schematic view illustrating a closed accommodation apparatus transported by the transporting apparatus 7 according to the present exemplary embodiment. In addition, FIG. 5 is a schematic view illustrating a bottom surface of the closed accommodation apparatus of FIG. 4. Hereinafter, the term “left and right” in the detailed description indicates the horizontal direction in FIG. 4, and the term, “up and down (top and bottom)” indicates the vertical direction in FIG. 4.

The accommodation container 20 which is an article to be transported includes a cover 22 as described above and an accommodation container body 26. Plural tiers of support units 27 (also referred to as “teeth”) that support the rear sides of the wafers W are installed at left and right of the inside of the accommodation container body 26. The flange 24 and support units 27 are formed of a conductive material independently from each other. In addition, the flange 24 and the support units 27 are configured to have the same potential through a conductive connection portion 28. That is, the 24, the support units 27 and the connection portion 28 have the same potential.

In addition, the accommodation container body 26 is formed with an opening 21 at the front side in FIG. 4 as described above, and the carry-out/-in of the wafers W is conducted through the opening 21. Engagement recesses 29 are formed at the top and bottom of the left and right of the inner periphery of the opening 21. When the engagement portions 33 of the cover 22 are engaged with the engagement recesses 29, the cover 22 is fixed to the accommodation container body 26.

The accommodation container 20 is typically configured in a size which may accommodate about 25 wafers W therein.

A rectangular head portion 23 is formed on the top surface of the accommodation container 20, and a flange 24 protruding in a rectangular shape is formed at the top end of the head portion 23.

As illustrated in FIG. 5, one or more positioning grooves 30 are formed on the bottom surface of the accommodation container 20. Although an example in which three positioning grooves are formed is illustrated in FIG. 3, the present exemplary embodiment is not limited thereto. As described above, for example, each of the mounting table 4, the accommodation shelf 5 and the holding table 6 is formed with positioning pins 8 which are engaged with the positioning grooves 30. When the accommodation container 20 has the positioning grooves 30 and the transporting apparatus 7 has the positioning pins 8 engaged with the positioning grooves 30, the accommodation container 20 is positioned at a predetermined position when the accommodation container 20 is disposed on the mounting table 4, the accommodation shelf 5 or the holding table 6.

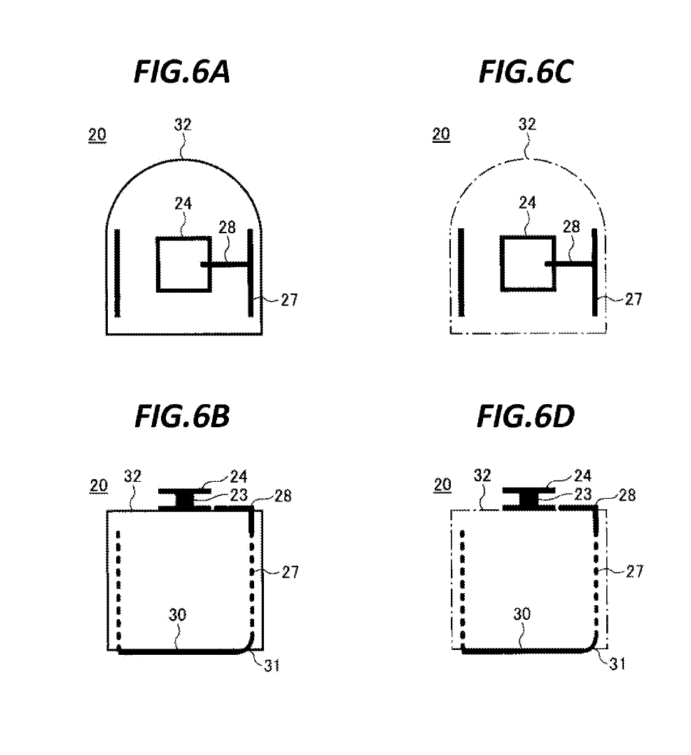

FIGS. 6A to 6D are schematic views for describing an electrifying property of the accommodation container according to the present exemplary embodiment. FIG. 6A is a schematic top plan view of an integrated accommodation container 20, FIG. 6B is a schematic side view of the integrated accommodation container 20. In addition, FIG. 6C is a schematic top plan view of an assembled accommodation container 20 and FIG. 6D is a schematic side view of the assembled accommodation container 20. In FIGS. 6A to 6D, elements with the same potential are indicated by the same type of lines, for example, by either the solid lines or the dot chain lines.

In the present exemplary embodiment, the integrated accommodation container 20 refers to an accommodation container in which at least a portion of the accommodation container body 26 and the support units 27 are integrally formed of a conductive material. That is, in the integrated accommodation container 20, the flange 24 and the support units 27, and the support units 27 and the positioning groove 30 are electrically connected through the connection units 28, 31, respectively. In addition, in FIG. 6B, although the support units 27 are indicated by broken lines, the supporting units 27 are integrally formed and have the same potential at all the areas. Further, herein, a portion other than the support units 27, the flange 24, the positioning groove 30, the connection units 28, and the connection unit 31 in the accommodation container body 26 is referred to as the other portion 32.

The integrated accommodation container 20 of the present exemplary embodiment is entirely charged with electricity (e.g., electrified) or discharged by an external cause such as, for example, contact with another material. That is, when a wafer W charged with electricity is accommodated in the integrated accommodation container 20, electric charges of the wafer W and the accommodation container 20 are not attenuated within a short time. Thus, the accommodated wafer W may attract particles from, for example, the inner wall of the accommodation container 20. Accordingly, when transporting wafers W using the integrated accommodation container 20, it is difficult to stably maintain the wafers W in a purified state.

Meanwhile, the assembled accommodation container 20 of the present exemplary embodiment refers to an accommodation container in which the flange 24, the supporting units 27, the positioning groove 30 and the connection units 28, 31 are formed of a conductive material but the other portion 32 is formed of a non-conductive material. Also, when a wafer W is accommodated in the assembled accommodation container 20, the electric charges of the wafer W and the accommodation container 20 are not attenuated within a short time. Thus, similarly to the integrated accommodation container, when transporting wafers W using the assembled accommodation container 20, it is difficult to stably maintain the wafers W in a purified state.

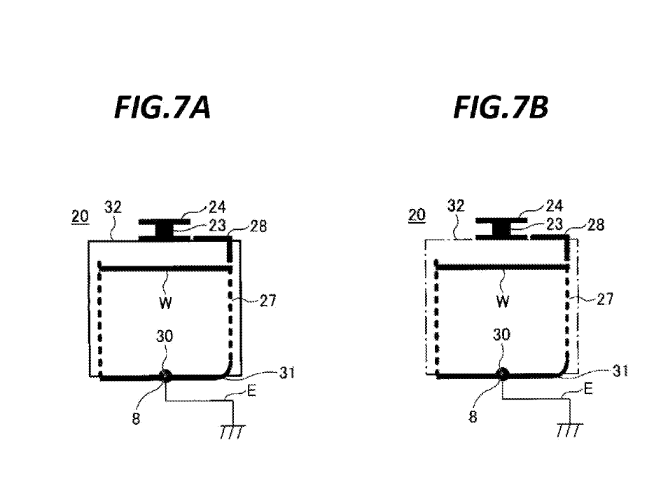

FIGS. 7A and 7B are schematic views for describing an electrifying property of an accommodation container 20 disposed in the transporting apparatus of the present exemplary embodiment. FIG. 7A is a schematic side view of an integrated accommodation container 20 disposed in the transporting apparatus 7 of the present exemplary embodiment, and FIG. 7B is a schematic side view of an assembled accommodation container 20 disposed in the transporting apparatus 7 of the present exemplary embodiment. In FIGS. 7A and 7B, elements with the same potential are indicated by the same type of lines, for example, by either the solid lines or the dot chain lines.

As illustrated in FIGS. 7A and 7B, in the transporting apparatus 7 of the present exemplary embodiment, a grounding element E is connected to the positioning pin 8. Thus, as illustrated in FIG. 7A, when the integrated accommodation container 20 is disposed on the transporting apparatus 7 of the present exemplary embodiment, the electric charges of the wafer W and the accommodation container 20 are easily attenuated and the potential thereof become approximately zero potential. Also, in the case of the assembled accommodation container 20 illustrated in FIG. 7B, the electric charges of the wafer W, the support units 27, the flange 24, the positioning groove 30, the connection unit 28, and the connection unit 31 are easily attenuated and the potentials thereof become approximately zero potentials. That is, when either one of the integrated accommodation container 20 or the assembled accommodation container 20 is used, the surface charges of the wafer W may be easily attenuated. Accordingly, when a wafer W is carried-in into the processing apparatus 1 for various processings, or carried-out from the processing apparatus 1 after the processings have been completed, the wafer W may be suppressed from being contaminated by, for example, particles within the accommodation container 20.

As for the conductive material used for each of the elements of the accommodation container 20, for example, a conductivity may be imparted to a thermoplastic resin such as, for example, polycarbonate resin, polyetheretherketone resin, polypropylene resin, or polybutylene terephthalate resin. The conductivity may be imparted by, for example, mixing a fiber conductive material such as a carbon fiber or a granular conductive material such as a carbon black.

As for another example of conductive material, a conductive resin composition obtained by mixing a predetermined amount of a conductive carbon black and a predetermined amount of a glass reinforcing filler to, for example, a thermoplastic resin to be described later may be used.

As for the thermoplastic resin, for example, polycarbonate resin, polypropylene resin, polybutylene terephthalate resin, and polyetheretherketone resin may be used. Among these, the polycarbonate resin may be used from the viewpoints of, for example, transparency, strength, impact resistance, and dimensional stability.

The content of the thermoplastic resin may be in the range of 50 mass % to 80 mass %. When the content of the thermoplastic resin is less than 50 mass %, workability may deteriorate. When the content exceeds 80 mass %, the effects obtained by adding the conductive carbon black and glass reinforcing filler may deteriorate.

As for the conductive carbon black, for example, Ketjen black, acetylene black, furnace black, and thermal black may be used. Among them, Ketjen black is preferable since it enables superior conductivity to be obtained with a small amount.

The content of the conductive carbon black may be in the range of 5 mass % to 25 mass %. When the content of the conductive carbon black is less than 5 mass %, a desired surface resistance value of the accommodation container may not be obtained. When the content of the conductive carbon black exceeds 25 mass %, strength or fluidity as a conductive resin composition may deteriorate and the dislodgment of carbon black particles may be caused so that particles may easily occur.

The glass filler in the present exemplary embodiment refers to an inorganic filer which contains glass as a main component, and, for example, glass fibers, glass flakes, and glass beads may be used as the examples of the glass filler. One of these fillers may be solely used or two or more of the fillers may be used in combination. For example, the glass flakes and the glass fibers may be used.

The content of the glass filler may be in the range of 15 mass % to 25 mass %. When the content of the glass filler is less than 15 mass %, a desired flexural modulus may not be obtained. When the content exceeds 25 mass %, the flexural of the accommodation container may increase unless the anisotropy is high in a direction perpendicular to the flowing direction of the obtained accommodation container.

Meanwhile, as the non-conductive material used for each of the components of the accommodation container 20, a thermoplastic resin such as, for example, a polyetherimide resin, a polyimide resin, and a polyamide imide resin may be used.

### First Exemplary Embodiment

In the first exemplary embodiment, descriptions will be made on an exemplary embodiment in which grounding effects obtained by providing a grounding element E for the positioning pins 8 of the transporting apparatus 7 were confirmed.

First, one kind of integrated accommodation containers 20 and three different kinds of assembled accommodation containers 20 were prepared. The accommodation containers 20 were disposed on the transporting apparatus 7 in such a manner that a positioning groove 30 of each of the accommodation containers 20 are engaged with a positioning pin 8 having a ground element E. The accommodation containers were left in that state for 21 hours and 30 minutes, and then the accommodation containers 20 were removed from the transporting apparatus 7. For the obtained accommodation containers 20, surface potentials were measured at plural places on each of the accommodation containers 20 using a handy type surface potential meter (manufactured by TREK JAPAN Co., Ltd.).

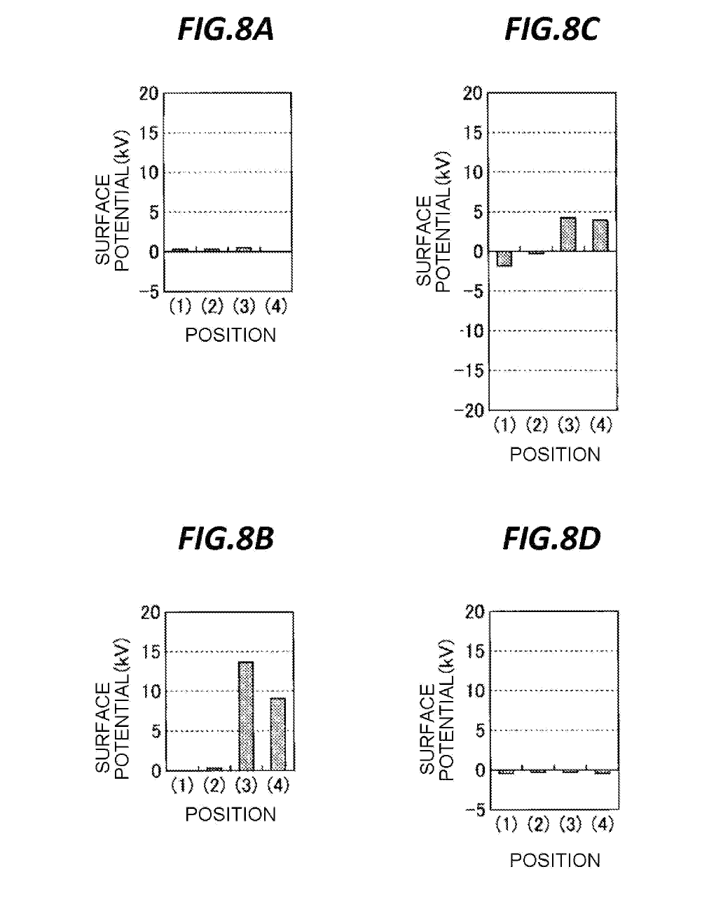

The measurement was carried out at the following measurement places (see, e.g., the horizontal axes of FIGS. 8A to 8D):

(1) flange 24,

(2) support unit 27,

(3) the other portion 32 (in the ceiling surface of accommodation container 20, a side opposite to the cover 22 from the flange 24), and

(4) the other portion 32 (in the ceiling surface of accommodation container 20, the cover 22 side from the flange 24)

The measurement results of surface potentials of accommodation containers 20 according to the present exemplary embodiment are represented in FIGS. 8A to 8D. FIG. 8A is an example of measurement results of surface potentials for an integrated accommodation container 20 (hereinafter, referred to as accommodation container 20 of Example 1) and FIGS. 8B to 8D are examples of measurement results of surface potentials for assembled accommodation containers 20 (hereinafter, referred to as accommodation containers of Examples 2 to 4, respectively). In addition, the vertical axes of FIGS. 8A to 8D represent surface potentials of wafers W and the horizontal axes represent the above-described measurement places.

In the example of the accommodation container 20 of Example 1, as illustrated in FIG. 8A, the surface potentials were approximately zero at all the measurement places including the support unit 27 where a wafer W is disposed. Meanwhile, in the examples of the accommodation containers of Examples 2 and 3, as illustrated in FIGS. 8B and 8C, the other portions 32 formed of a non-conductive material had a surface potential of several kV or more. However, in the case of the accommodation containers of Examples 2 to 4, the potentials at the support units 27 where the wafer W is disposed were also approximately zero. That is, for any of the integrated or assembled accommodation containers, the surface potential of the support unit 27 becomes approximately zero when a wafer W is disposed on the transporting apparatus 7 having the grounding element E of the present exemplary embodiment. Thus, when a wafer W charged with electricity is accommodated within the accommodation containers 20, the surface potential of the wafer W is easily attenuated so that the surface potential of the wafer W becomes an approximately zero potential. As a result, the contamination of the wafer W from particles existing within the accommodation containers 20 may be suppressed.

Although a configuration in which the positioning pins 8 has a grounding element E has been described in the first exemplary embodiment, the present disclosure is not limited thereto. The arm unit 17 or the fixing unit 41 may have the grounding element E.

### Second Exemplary Embodiment

In the second exemplary embodiment, descriptions will be made on an exemplary embodiment in which it has been confirmed that the attraction of particles to a wafer W may be suppressed when the positioning pins 8 of the transporting apparatus 7 are provided with a grounding element E.

The number of particles existing on the surfaces of wafers W was measured using a light scattering type foreign substance measuring apparatus (SP1TBI manufactured by KLA Tencor). Then, the accommodation containers 20 of Examples 1 to 4 were disposed on the transporting apparatus 7 having a grounding element. The accommodation containers 20 were installed in advance in a clean room (e.g., class 100). Next, the wafers W were charged with electricity to +5 kV and left for 30 minutes. The wafers W were then taken out and the number of particles on the surfaces of the wafers W was measured. As a comparative example, for the wafers W disposed on the transporting apparatus 7 which is not provided with a grounding element E, the number of particles existing on the surfaces of the wafers W was measured as well.

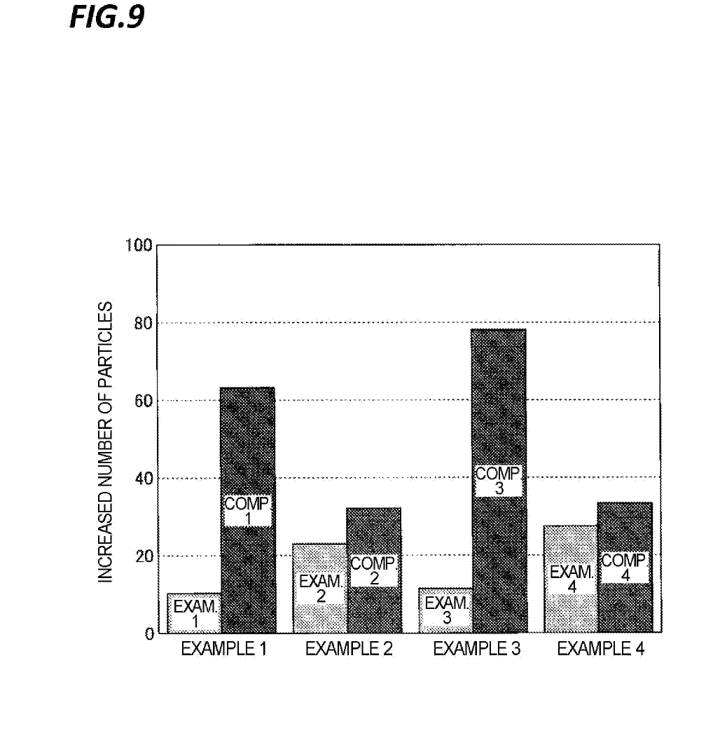

FIG. 9 illustrates a graph for describing the increase of the number of particles in the accommodation containers 20 according to the exemplary embodiments of the present disclosure. In the graph of FIG. 9, the vertical axis represents the increased amount of particles before and after the above-described electrification and the horizontal axis represents the kinds of used accommodation containers 20.

As illustrated in FIG. 9, the wafers W disposed in the transporting apparatus 7 according to an exemplary embodiment of the present disclosure which was provided with a grounding element E revealed a small fluctuation in the increased amount in the number of particles among the used accommodation containers 20, and in all the accommodation containers 20, the increased amount in the number of particles was 30 or less.

Meanwhile, the wafers W disposed on the transporting apparatus 7 of the comparative example which was not provided with a grounding element revealed substantial increase in the number of particles and the fluctuation in the increased number of particles among the used accommodation container 20 was high.

Thus, when either integrated or assembled accommodation containers are disposed on the transporting apparatus of the exemplary embodiments of the present invention which is provided with a grounding element, the surface potentials of the wafers W accommodated in the accommodation containers 20 are easily attenuated and become approximately zero potentials. As a result, the contamination of the wafers W by the particles existing within the accommodation containers 20 may be suppressed.

Although a configuration in which the positioning pins 8 are provided with a grounding element E has been described in the second exemplary embodiment, the present disclosure is not limited thereto. Either the arm unit 17 or the fixing unit 41 may be provided with the grounding element E.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A transporting apparatus comprising:
a holding table having a first positioning pin that positions an article to be transported and configured to transfer an object to be processed which is accommodated in the article;
an arm unit configured to grasp the article so as to dispose the article on the holding table; and
a support unit configured to fix the article disposed on the holding table,
wherein at least one of the first positioning pin, the arm unit, and the support unit includes a ground element.

2. The transporting apparatus of claim 1, wherein the first positioning pin have the grounding element, and the article to be transported has a positioning groove which is engaged with the first positioning pin.

3. The transporting apparatus of claim 1, further comprising:
a mounting table having a second positioning pin that positions the article to be transported and configured to carry in/out the article to be transported; and
an accommodation shelf having a third positioning pin that positions the article to be transported and configured to accommodate the article to be transported,
wherein at least one of the second positioning pin and the third positioning pin has the grounding element.

4. The transporting apparatus of claim 2, wherein the first positioning pin is configured by three pins and at least one of the three pins includes a grounding element.

5. The transporting apparatus of claim 3, wherein each of the second positioning pin and third positioning pin is configured by three third pins and at least one of the three pins includes a grounding element.

6. The transporting apparatus of claim 1, wherein the arm unit has the grounding element, and the article to be transported includes a flange to be grasped by the arm unit.

7. The transporting apparatus of claim 1, wherein the support unit includes the grounding element, the holding table is configured to be movable, and the support unit is engaged with at least a portion of the top surface of the article to be transported so as to fix the article to be transported which is disposed on the holding table.

8. The transporting apparatus of claim 1, wherein the article to be transported is a closed cassette in which at least a semiconductor wafer is accommodated.

9. A processing apparatus comprising:
the transporting apparatus recited in claim 1; and
a heat treatment apparatus configured to perform a heat treatment for the object to be processed which is transferred by the holding table.
